(19) United States
(12) Patent Application Publication
(10) Pub. No.: US 2010/0096006 A1
(43) Pub. Date: Apr. 22, 2010

(54) MONOLITHIC IMOD COLOR ENHANCED PHOTOVOLTAIC CELL

(75) Inventors: Jonathan C. Griffiths, Fremont, CA (US); Manish Kothari, Cupertino, CA (US)

Correspondence Address: KNOBBE, MARTENS, OLSON & BEAR, LLP, 2040 MAIN STREET, FOURTEENTH FLOOR, IRVINE, CA, 92614, US

(73) Assignee: QUALCOMM MEMS TECHNOLOGIES, INC., San Diego, CA (US)

(21) Appl. No.: 12/396,000

(22) Filed: Mar. 2, 2009

Related U.S. Application Data
(60) Provisional application No. 61/106,058, filed on Oct. 16, 2008.
(60) Provisional application No. 61/139,839, filed on Dec. 22, 2008.

(51) Int. Cl. H01L 31/00; B05D 5/12

(52) U.S. Cl. 136/256; 427/74

(57) ABSTRACT

Devices incorporating an interferometric stack in a photovoltaic device and method of manufacturing a photovoltaic device comprising an interferometric stack. In one example, a photovoltaic device includes a photovoltaic active layer, an absorber layer, and a first optical resonant cavity layer. The optical resonant cavity layer is disposed between the absorber layer and photovoltaic active layer forming an interferometric modulator. The interferometric modulator is configured to reflect a uniform color. In another example, a method of manufacturing a photovoltaic device includes depositing a photovoltaic active layer on an interferometric stack. The interferometric stack can include an absorber layer and a first optical resonant cavity. The photovoltaic active layer is deposited on the optical resonant cavity and the formed photovoltaic device is reflects a uniform color.

### CROSS-REFERENCE TO RELATED APPLICATIONS

This application claims the benefit of U.S. Provisional Application No. 61/106,058 filed on Oct. 16, 2008, titled “HIGH EFFICIENCY INTERFEROMETRIC COLOR FILTERS FOR PHOTOVOLTAIC MODULES,” and U.S. Provisional Application No. 61/139,839 filed on Dec. 22, 2008, titled “MONOLITHIC IMOD COLOR ENHANCED PHOTOVOLTAIC CELL,” both of which are hereby expressly incorporated by reference in their entireties.

### BACKGROUND OF THE INVENTION

1. Field of the Invention

The invention relates generally to the field of optoelectronic transducers that convert optical energy into electrical energy, for example, photovoltaic cells.

2. Description of the Related Art

For over a century fossil fuel such as coal, oil, and natural gas has provided the main source of energy in the United States. The need for alternative sources of energy is increasing. Fossil fuels are a non-renewable source of energy that is depleting rapidly. The large scale industrialization of developing nations such as India and China has placed a considerable burden on the available fossil fuel. In addition, geopolitical issues can quickly affect the supply of such fuel. Global warming is also of greater concern in recent years. A number of factors are thought to contribute to global warming; however, widespread use of fossil fuels is presumed to be a main cause of global warming. Thus there is an urgent need to find a renewable and economically viable source of energy that is also environmentally safe. Solar energy is an environmentally safe renewable source of energy that can be converted into other forms of energy such as heat and electricity.

Photovoltaic (PV) cells convert optical energy to electrical energy and thus can be used to convert solar energy into electrical power. Photovoltaic solar cells can be made very thin and modular. PV cells can range in size from a about few millimeters to ten's of centimeters, or larger. The individual electrical output from one PV cell may range from a few milliwatts to a few watts. Several PV cells may be connected electrically and packaged in arrays to produce a sufficient amount of electricity. PV cells can be used in a wide range of applications such as providing power to satellites and other spacecraft, providing electricity to residential and commercial properties, charging automobile batteries, etc.

While PV devices have the potential to reduce reliance upon hydrocarbon fuels, the widespread use of PV devices has been hindered by inefficiency and aesthetic concerns. Accordingly, improvements in either of these aspects could increase usage of PV devices.

### SUMMARY OF THE INVENTION

Certain embodiments of the invention include photovoltaic cells or devices integrated with interferometric modulators to reflect a visible color or colors to a viewer. Such interferometrically colored photovoltaic devices may be made to reflect any of a broad range of colors, according to the needs of a particular application. This may make them more aesthetically pleasing and therefore more useful in building or architectural applications.

According to one embodiment, the invention comprises a photovoltaic device defining a front side on which light is incident, the photovoltaic device comprising a photovoltaic active layer having a front side and a back side, an absorber layer, and a first optical resonant cavity defined by the front side of the photovoltaic active layer and the absorber layer. In some embodiments, the first optical resonant cavity may comprise a first spacer layer and in other embodiments, the spacer layer may comprise a transparent conductive oxide. In some embodiments, the photovoltaic device may comprise a second optical resonant cavity defined by a reflector and the back side of the photovoltaic active layer.

According to another embodiment, the invention comprises a method of manufacturing a photovoltaic device, the method comprising providing an interferometric stack comprising an absorber layer on a substrate and a first optical resonant cavity defined on a first side by the absorber layer and depositing a photovoltaic active layer on the interferometric stack, the photovoltaic active layer defining a second side of the first optical resonant cavity. In some embodiments, the first optical resonant cavity may comprise a first spacer layer and in other embodiments, the spacer layer may comprise a transparent conductive oxide.

According to another embodiment, the invention comprises a photovoltaic device comprising an interferometric modulator comprising a photovoltaic active layer. In some embodiments, the photovoltaic active layer has a front side and a back side and the device further comprises a first optical resonant cavity defined by the front side of the photovoltaic active layer. In some embodiments, the photovoltaic active layer comprises a thin film photovoltaic material.

According to another embodiment, the invention comprises a photovoltaic device defining a front side on which light is incident, the photovoltaic device comprising a first means for partially reflecting light incident on the front side, a second means for partially reflecting light incident on the front side that has passed through the first means, and a first optical resonant cavity defined by the first means and the second means. In one aspect, the first means comprises a photovoltaic active layer. In another aspect, the second means comprises an absorber layer.

### BRIEF DESCRIPTION OF THE DRAWINGS

Example embodiments disclosed herein are illustrated in the accompanying schematic drawings, which are for illustrative purposes only. The drawings are not drawn to scale, unless otherwise stated as such, or necessarily reflect relative sizes of illustrated aspects of the embodiments.

FIG. 1 schematically illustrates a theoretical optical interferometric cavity

FIG. 2A schematically illustrates an interferometric modulator (IMOD) including an absorber and a spacer layer.

FIG. 2B is a block diagram of an IMOD, similar to that of FIG. 2A, comprising an absorber layer, a spacer layer, and a reflector.

FIG. 2C schematically illustrates an IMOD where the spacer layer includes an air gap formed by posts or pillars between the absorber and reflector layers.

FIG. 2D shows total reflection versus wavelength of an IMOD with a spacer layer configured to reflect yellow for normally incident and reflected light.

FIG. 3A schematically illustrates a photovoltaic cell comprising a p-n junction.

FIG. 3B is a block diagram that schematically illustrates a photovoltaic cell comprising a deposited thin film photovoltaic active material.

FIGS. 3C and 3D are schematic plan and isometric sectional views, respectively, depicting an exemplary solar photovoltaic device with visible reflective electrodes on the front side.

FIG. 4A and 4B are block diagrams that schematically illustrate photovoltaic cells comprising interferometrically enhanced stacks.

FIG. 4C is a block diagram that schematically illustrates a photovoltaic cell comprising two interferometrically enhanced stacks.

FIG. 4D schematically illustrates an embodiment of a color photovoltaic (PV) device incorporating an interferometric stack.

FIG. 4E shows total reflection versus wavelength from the front (substrate) side of a photovoltaic cell configured as shown in FIG. 4A.

FIG. 4F shows a chromaticity diagram depicting the color reflected from the front (substrate) side of a photovoltaic cell comprising an a-silicon active layer configured as shown in FIG. 4A as the thickness of the first spacer layer is varied.

FIG. 4G shows a chromaticity diagram depicting the color reflected from the front (substrate) side of a photovoltaic cell comprising a copper indium gallium diselenide (CIGS) active layer configured as shown in FIG. 4A as the thickness of the first spacer layer is varied.

FIG. 4H shows a chromaticity diagram depicting color transmitted through a PV cell or device configured as shown in FIG. 4A as the thickness of the first spacer layer is varied.

FIG. 41 shows a chromaticity diagram depicting color reflected from the rear (PV active material) side of a PV cell configured as shown in FIG. 4A as the thickness of the first spacer layer is varied.

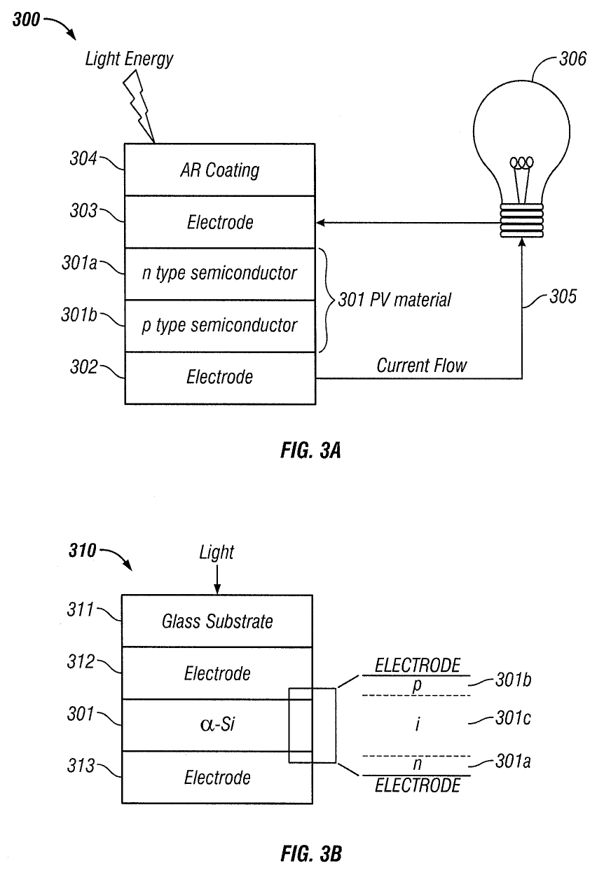

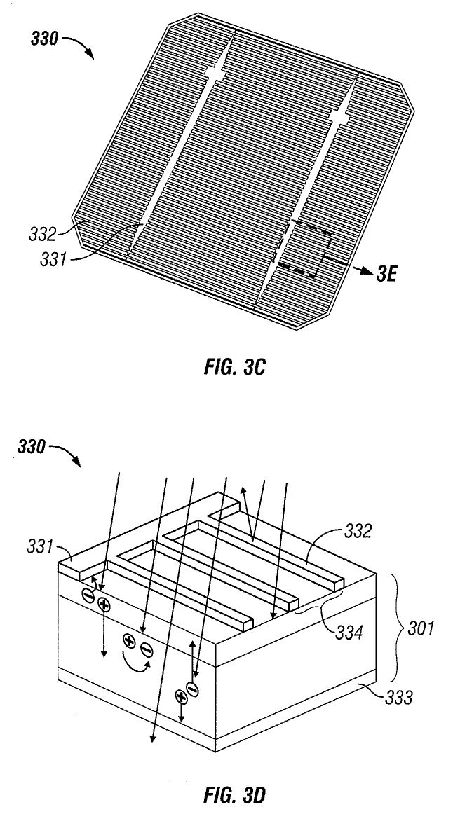

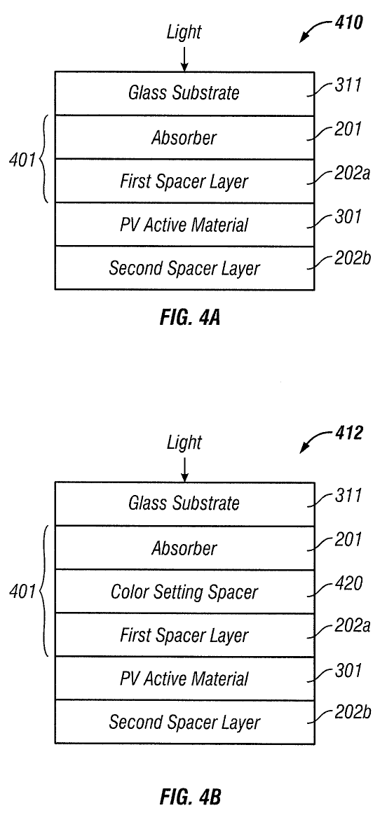

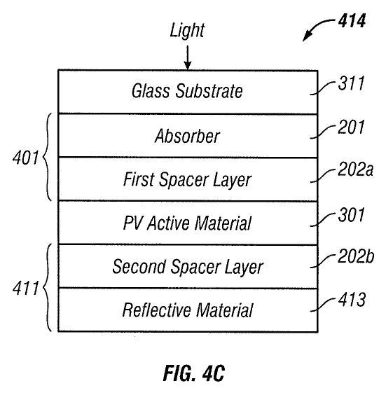

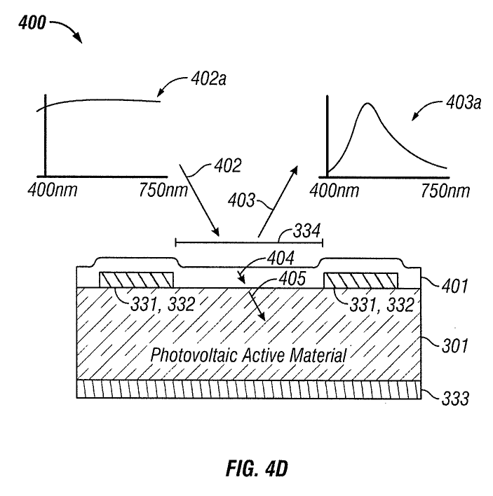

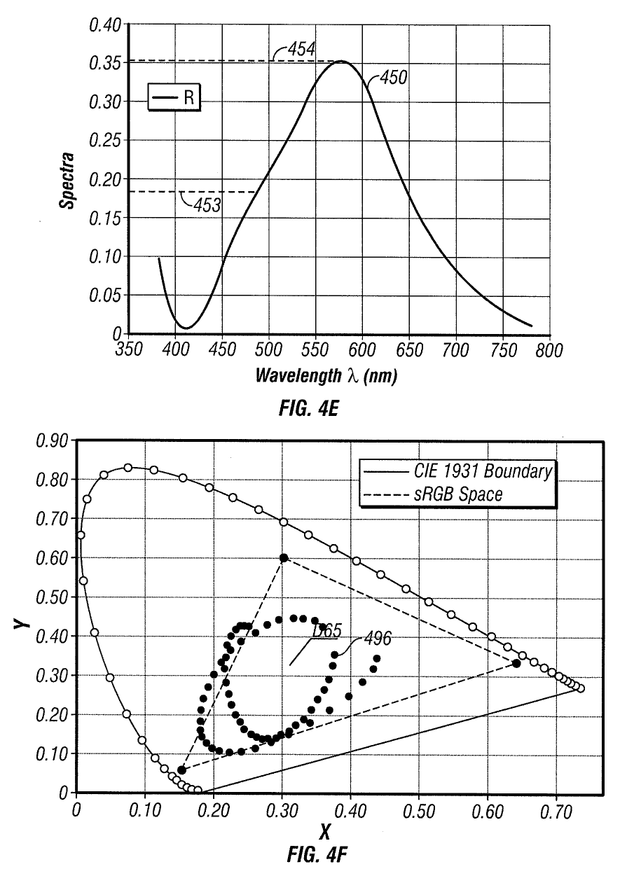

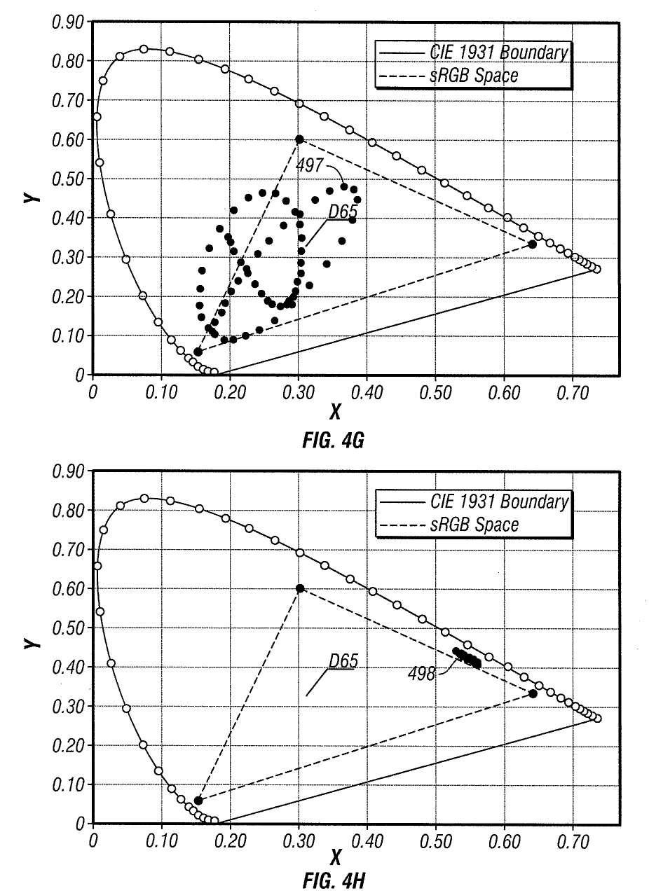

FIG. 4J shows light transmission through a first spacer layer versus wavelength of a photovoltaic cell configured as shown in FIG. 4A and of a photovoltaic cell configured as shown in FIG. 3B.

FIGS. 5A-5D illustrate embodiments of patterned interferometric stacks displaying different colors in different regions to form images over a static display comprising a color PV device.

FIGS. 6A-6E are schematic cross-sectional views illustrating steps in a process of manufacturing a PV device incorporating an IMOD stack.

### DETAILED DESCRIPTION OF CERTAIN EMBODIMENTS

One issue hindering widespread adoption of photovoltaic (PV) devices on available surfaces for conversion of light energy into electric energy or current is the difficulty of integrating them due to their color, in various applications, for example, on signs, billboards, or buildings. The active PV material itself may appear dark. Some shiny conductors/electrodes are also often visible. Both of these factors can hinder the blending of PV devices with surrounding materials due to aesthetic concerns. Embodiments of PV cells described herein may have interferometric (absorber-spacer) stacks coupled with PV active material layers that act as partial or composite reflectors to create an IMOD stack. Such embodiments can be designed to enhance reflections of select wavelength spikes or peaks in the visible range using the principles of optical interference. Reflecting selective wavelengths can cause the PV cell to appear a certain color to a viewer. Thus, the PV cell can be designed to appear a certain color according to the needs of a particular application. The interferometric reflection or transmission is governed by the dimensions and fundamental material properties of the materials making up the interferometric thin film stack. Accordingly, the coloring effect is not as susceptible to fading over time compared to common dyes or paints.

Although certain embodiments and examples are discussed herein, it is understood that the inventive subject matter extends beyond the specifically disclosed embodiments to other alternative embodiments and/or uses of the invention and obvious modifications and equivalents thereof. It is intended that the scope of the inventions disclosed herein should not be limited by the particular disclosed embodiments. Thus, for example, in any method or process disclosed herein, the acts or operations making up the method/process may be performed in any suitable sequence and are not necessarily limited to any particular disclosed sequence. Various aspects and features of the embodiments have been described where appropriate. It is to be understood that not necessarily all such aspects or features may be achieved in accordance with any particular embodiment. Thus, for example, it should be recognized that the various embodiments may be carried out in a manner that achieves or optimizes one feature or group of features as taught herein without necessarily achieving other aspects or features as may be taught or suggested herein. The following detailed description is directed to certain specific embodiments of the invention. However, the invention can be embodied in a multitude of different ways. The embodiments described herein may be implemented in a wide range of devices that incorporate photovoltaic devices for conversion of optical energy into electrical current. For example, it is contemplated that the embodiments may be implemented in billboards, signs, architectural structures, in solar panels placed on or around residential structures, commercial buildings, and vehicles including boats and cars.

In this description, reference is made to the drawings wherein like parts are designated with like numerals throughout. As will be apparent from the following description, the embodiments may be implemented in a variety of devices that comprise photovoltaic active material.

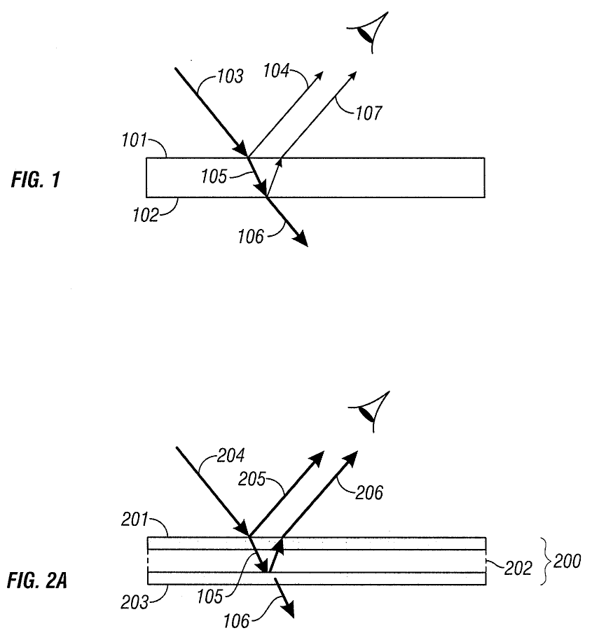

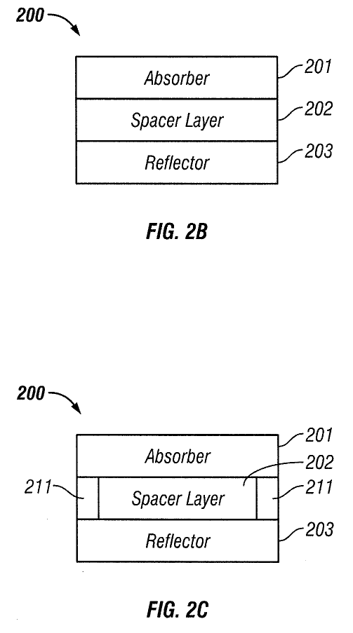

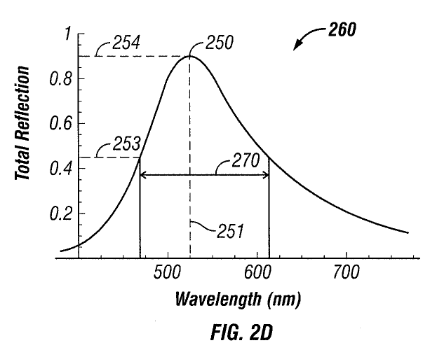

Initially, FIGS. 1-2D illustrate some optical principles and different embodiments of IMODs that are useful for integrating with photovoltaic devices, as described with respect to FIGS. 4-6E. FIGS. 3A-3D illustrate embodiments of photovoltaic device constructions with which interferometric stacks can be integrated to form IMODs. FIGS. 4-6E illustrate embodiments in which interferometric stacks are integrated with photovoltaic devices, and properties of these embodiments.

FIG. 1 is a schematic illustrating an example of an optical resonant cavity. A particular example of such an optical resonant cavity is a soap film which may produce a spectrum of reflected colors. An optical resonant cavity is a structure that can be used to interferometrically manipulate light. The optical resonant cavity shown in FIG. 1 comprises upper and lower interfaces 101 and 102, defining a space or volume therebetween. The two interfaces 101 and 102 may be opposing surfaces on the same layer. For example, the two interfaces 101 and 102 may comprise surfaces on a glass or plastic plate or sheet or a film of glass, plastic, or any other transparent material. Air or other media may surround the plate, sheet, or film. The optical resonant cavity may have one material on one side of it at the upper interface 101, and a separate (e.g., different) material on the other side at the lower interface 102. The materials forming interfaces 101, 102 with the optical resonant cavity may be a metallic or partially reflecting layer, a transparent media, or a dielectric, for example, air. Materials forming interfaces 101, 102 with the optical resonant cavity may be the same, or may be different. In the illustrated example, light partially reflects and partially transmits at each of the interfaces 101, 102.

A ray of light 103 that is incident on the front surface 101 of the optical resonant cavity is partially reflected as indicated by the light path 104 and partially transmitted through the front surface 101 along light path 105. Ray 103 may have a broad spectral distribution of light. For example, ray 103 may comprise white light, and therefore may have significant components from a broad range of wavelengths within the visible range, 450 nm to 700 nm as well as wavelengths outside the visible range. The transmitted light ray 105 may be partially reflected along light path 107 and partially transmitted out of the resonant cavity along light path 106. The optical properties, including the thickness, of the optical resonant cavity, as well as the properties of the surrounding materials may affect both the amplitude and phase of light reflected from both interface 101 and interface 102. Therefore, rays 104 and 107 will each have an amplitude and a phase, depending on the properties of the optical resonant cavity, and the surrounding media. The example is simplified by omission of multiple internal reflections, as will be appreciated by the skilled artisan.

For purposes of the discussions provided herein, the total intensity of light reflected from the optical resonant cavity is a coherent superposition of the two reflected light rays 104 and 107. With such coherent superposition, both the amplitude and the phase of the two reflected beams contribute to the aggregate intensity. This coherent superposition is referred to as interference. The two reflected rays 104 and 107 may have a phase difference with respect to each other. In some embodiments, the phase difference between the two waves may be 180 degrees (180°) and cancel each other out. If the phase and the amplitude of the two light rays 104 and 107 are configured so as to reduce the intensity at a particular wavelength then the two light beams are referred to as interfering destructively at that wavelength. If on the other hand the phase and the amplitude of the two light beams 104 and 107 are configured so as to increase the intensity at a particular wavelength then the two light rays are referred to as interfering constructively at that wavelength. The phase difference depends on the optical path difference of the two paths, which depends both on the thickness of the optical resonant cavity, the index of refraction of the material between the two interfaces 101 and 102, and whether the indices of surrounding materials are higher or lower than the material forming the optical resonant cavity. The phase difference is also different for different wavelengths in the incident beam 103. Accordingly, rays 104 and 107 may have a phase difference relative to each other, and this phase difference may vary with wavelength. Thus some wavelengths may interfere constructively and some wavelengths may interfere destructively. In general, the colors and the total intensity reflected and transmitted by the optical resonant cavity thus depend on the thickness and the material forming the optical resonant cavity and surrounding media. The reflected and transmitted wavelengths also depend on viewing angle, different wavelength being reflected and transmitted at different angles.

The principles described above can be used to construct structures that will interferometrically selectively reflect and/or transmit wavelength spectra or range(s) of visible wavelengths of incident light depending on the wavelength of the light. A structure which affects the reflection or transmission of light depending on its wavelength using the principles of interference can be referred to as an interferometric thin film stack, or more simply an interferometric stack. In some embodiments, the interferometric stack is an interferometric modulator (IMOD) that includes an optical resonant cavity that is formed between an optical absorber and a reflector. Alternatively, the stack may only include an absorber and a spacer layer and the reflector can be provided separately to form an IMOD. In this scenario the spacer layer is an optically resonant layer and the optical resonant cavity is formed between the absorber and reflector when the reflector is placed on the spacer layer. In this scenario, the optical resonant cavity formed by the absorber and reflector layers comprises the spacer layer. The separately provided reflector may be a partial or full reflective layer. Other layer(s) having their own functions in the underlying devices may serve as a partial or composite reflector. As will be appreciated by the skilled artisan, where the optical path length for light reflected from the interferometric stack is on about the same order of magnitude as the visible wavelength, the visual effect can be quite stark. As the optical path length increases and exceeds the coherence length of white light (e.g., 5000 nm and above), interference is no longer possible as the phase of the light loses its coherence so that the visual interferometric color effect is lost.

FIG. 2A depicts an embodiment of an interferometric modulator (IMOD) 200. An IMOD 200 includes an absorber layer 201 and a spacer layer 202, which together form an interferometric stack, and a reflector layer 203. In FIG. 2A, the spacer layer 202 is sandwiched between two reflective surfaces. In this particular embodiment, the absorber layer 201 defines the top of an optical resonant cavity which comprises spacer layer 202 while a bottom reflector layer 203 defines the bottom of the optical resonant cavity. The reflector layer 203 may include a single layer or multiple layers of material which affect its reflectance. The thickness of the absorber 201 and reflector 203 layers may be selected to control relative amounts of reflectance and transmittance of light. Both the absorber and reflector layers may comprise metal, and both can be configured to be partially transmissive. As shown in FIG. 2A, the ray of light 204 that is incident on the absorber layer 201 of the optical interference cavity may be partially reflected out of the optical interference cavity along each of the paths 205 and 206. The illumination field as viewed by an observer on the front or incident side is a superposition of the two reflected rays 205 and 206. The amount of light substantially reflected or transmitted 106 through the bottom reflector 203 can be significantly increased or reduced by varying the thickness and the composition of the reflector layers, whereas the apparent color of reflections is largely determined by the interference effect governed by the size or thickness of the spacer layer 202 and the material properties of the absorber layer 201 that determine the difference in optical path length between the rays 205 and 206. Modulating the bottom reflector thickness 203 (or omitting in favor of whatever reflectivity is provided by an interface between the spacer layer 202 and an underlying medium) will modulate the intensity of the reflected color versus the overall reflectivity of the IMOD 200 and thus influence the intensity of transmissions 106 through the IMOD 200.

In some IMODs, the spacer layer 202 is defined by a solid layer, for example, an optically transparent dielectric layer, or plurality of layers. In other IMODs, the spacer layer 202 is defined by an air gap or combination of optically transparent layer(s) and an air gap. The thickness of the spacer layer 202 may be tuned to maximize or minimize the reflection of one or more specific colors of the incident light. The color or colors reflected by the optical interference cavity may be changed by changing the thickness of the spacer layer. Accordingly, the color or colors reflected by the optical interference cavity may depend on the thickness of the spacer layer 202.

FIG. 2B is a simplified schematic of an embodiment of an IMOD 200. As illustrated, the IMOD 200 is an absorber-spacer layer stack comprising an absorber 201, a partial or full reflector 203, and spacer layer 202 between the absorber 201 and the reflector 203. The material chosen for the absorber 201 may be selected by the extinction coefficient, κ, for the particular material. The extinction coefficient for a particular substance is a measure of how well it scatters and absorbs electromagnetic radiation, as defined by Equation 1 (below). If electromagnetic waves can pass through a material very easily, the material has a low extinction coefficient. On the other hand, if the electromagnetic waves cannot penetrate a material, but become “extinct” or “die out” within it, the extinction coefficient is high.

$$κ = \frac{λ}{4 π} α \qquad [ Equation 1 ]$$

In Equation 1, the extinction coefficient of a particular material is represented by κ, the absorption coefficient of that material is represented by α, and λ represents the vacuum wavelength of the electromagnetic wave (not the wavelength of the electromagnetic wave in the material). As can be seen by examining Equation 1, the extinction coefficient, κ, is directly related to the product of the absorption coefficient, α, and the wavelength of the electromagnetic wave in a vacuum, λ. The absorber 201 may comprise various materials, for example, molybdenum (Mo), titanium (Ti), tungsten (W), chromium (Cr), etc., as well as alloys, for example, MoCr. The absorber may be between about 20 and 300 Å. The reflector 203 may, for example, comprise a metal layer, for example, aluminum (Al), silver (Ag), molybdenum (Mo), gold (Au), Cr, etc., and may be thick enough to be opaque (e.g., 300 nm). In other IMODs, the reflector 203 is a partial reflector and may be as thin as 20 Å. Generally, a reflector 203 that is a partial reflector will be between about 20 and 300 Å. The spacer layer 202 may comprise an air gap and/or one or more optically transparent materials. The spacer layer 202 may be defined by a single layer of material disposed between the reflector 203 and the absorber layer 201. In such embodiments, the material may include an optically resonant material, for example, a transparent conductor or transparent dielectric. Exemplary transparent materials for the spacer layer 202 may comprise dielectrics, for example, silicon dioxide (SiO₂), titanium dioxide (TiO₂), magnesium fluoride (MgF₂), chromium (III) oxide (Cr₃O₂), silicon nitride (Si₃N₄), etc., as well as transparent conductive oxides (TCOs), for example, indium tin oxide (ITO), zinc oxide (ZnO), etc. More generally, any dielectric with an index of refraction (n) between 1 and 3 may form a suitable spacer layer. In situations where a conductive color IMOD stack is required, the spacer layer 202 may comprise conductive transparent films. In some IMODs, the spacer layer 202 can comprise a composite structure comprising multiple materials that may include two or more of an air gap, a transparent conducting material, for example, a transparent conductive oxide, and a transparent dielectric layer. A possible function of multiple layers and/or air gaps is that selected layers of the stack may serve multiple functions, for example, device passivation or scratch resistance in addition to its optical role in the IMOD 200. In some embodiments, the spacer layer 202 may comprise one or more partially transparent materials, whether conductive or dielectric.

With reference to FIG. 2C, in other embodiments the thickness of the spacer layer 202 may comprise an air gap 202 supported by spacers 211, for example, rails, posts or pillars. Within the IMOD 200, the spacer layer 202 may be an air gap that is static, or one that is dynamic, e.g., variable using, for example, MEMS technology.

An interferometric modulator (IMOD) structure 200 such as shown in FIGS. 2B or 2C selectively produces a desired reflection output using optical interference. This reflected output may be “modulated” by selection of the thickness and optical properties of a static spacer layer 202, as well as the thickness and optical properties of the absorber 201 and the reflector 203. The color observed by a viewer viewing the surface of the absorber 201 will correspond to those frequencies that are substantially reflected out of the IMOD 200 and are not substantially absorbed or destructively interfered by the various layers of the IMOD 200. The frequencies that interfere and are not substantially absorbed can be varied by selecting the thickness of the spacer layer 202.

FIG. 2D illustrates a graph of reflectance of an IMOD (for example, the IMOD 200 of FIG. 2B) versus wavelength as seen from a direction normal or perpendicular to the front surface of the interferometric stack. This graph depicts the wavelength spectrum of the reflected light which may generally be different from the wavelength spectrum of the light incident on the IMOD. In the illustrated graph, the reflectance is maximized around a peak 250 of approximately 540 nm. Hence, the peak wavelength 251 is approximately 540 nm (yellow). Peak 250 also has a half-peak bandwidth, which is the width of the peak at a reflectance 253 equal to half of the peak or maximum reflectance 254. As mentioned previously, the location of the peak of the total reflection curve can be shifted by changing either the thickness or material of the spacer layer 202 or by changing the material and thickness of one or more layers in the IMOD. The location of the peak may depend on viewing angle. As illustrated, there is only one peak; however, there may be multiple peaks of different amplitude depending on the height or thickness of the spacer layer. As will be known to one of skill in the art, the IMOD may also be configured to modulate absorption or transmittance as well as reflectance.

FIG. 3A shows a photovoltaic (PV) cell 300. A photovoltaic cell can convert light energy into electrical energy or current. A PV cell is an example of a renewable source of energy that has a small carbon footprint and has less impact on the environment. Using PV cells can reduce the cost of energy generation. PV cells can have many different sizes and shapes, e.g., from smaller than a postage stamp to several inches across. Several PV cells can often be connected together to form PV cell modules that may be up to several feet long and a few feet wide. Modules, in turn, can be combined and connected to form PV arrays of different sizes and power output.

The size of an array can depend on several factors, for example, the amount of sunlight available in a particular location and the needs of the consumer. The modules of the array can include electrical connections, mounting hardware, power-conditioning equipment, and batteries that store solar energy for use when the sun is not shining. A PV device can be a single cell with its attendant electrical connections and peripherals, a PV module, a PV array, or solar panel. A PV device can also include functionally unrelated electrical components, e.g., components that are powered by the PV cell(s).

With reference to FIG. 3A, a PV cell comprises a PV active region 301 disposed between two electrodes 302, 303. In some embodiments, the PV cell comprises a substrate on which a stack of layers is formed. The PV active layer of a PV cell may comprise a semiconductor material, for example, silicon. In some embodiments, the active region may comprise a p-n junction formed by contacting an n-type semiconductor material 301a and a p-type semiconductor material 301b as shown in FIG. 3A. Such a p-n junction may have diode-like properties and may therefore be referred to as a photodiode structure as well.

The PV active material 301 is sandwiched between two electrodes that provide an electrical current path. The back electrode 302 can be formed of aluminum, silver, or molybdenum or some other conducting material. The back electrode can be rough and unpolished. The front electrode 303 may be designed to cover a significant portion of the front surface of the p-n junction so as to lower contact resistance and increase collection efficiency. In embodiments wherein the front electrode 303 is formed of an opaque material, the front electrode 303 may be configured to leave openings over the front of the PV active layer to allow illumination to impinge on the PV active layer. In some embodiments, the front and back electrodes can include a transparent conductor, for example, transparent conducting oxide (TCO), for example, tin oxide (SnO₂) or indium tin oxide (ITO). The TCO can provide electrical contact and conductivity and simultaneously be transparent to the incoming light. In some embodiments, the PV cell can also comprise an anti-reflective (AR) coating 304 disposed over the front electrode 303. The AR coating 304 can reduce the amount of light reflected from the front surface of the PV active material 301.

When the front surface of the PV active material 301 is illuminated, photons transfer energy to electrons in the active region. If the energy transferred by the photons is greater than the band-gap of the semiconducting material, the electrons may have sufficient energy to enter the conduction band. An internal electric field is created with the formation of the p-n junction. The internal electric field operates on the energized electrons to cause these electrons to move, thereby producing a current flow in an external circuit 305. The resulting current flow can be used to power various electrical devices, for example, a light bulb 306 as shown in FIG. 3A.

The PV active material layer(s) can be formed by any of a variety of light absorbing, photovoltaic materials, for example, crystalline silicon (c-silicon), amorphous silicon (α-silicon), cadmium telluride (CdTe), copper indium diselenide (CIS), copper indium gallium diselenide (CIGS), light absorbing dyes and polymers, polymers dispersed with light absorbing nanoparticles, III-V semiconductors, for example, GaAs, etc. Other materials may also be used. The light absorbing material(s) where photons are absorbed and transfer energy to electrical carriers (holes and electrons) is referred to herein as the PV active layer or material of the PV cell, and this term is meant to encompass multiple active sub-layers. The material for the PV active layer can be chosen depending on the desired performance and the application of the PV cell.

In some arrangements, the PV cell can be formed by using thin film technology. For example, in one embodiment, where optical energy passes through a transparent substrate, the PV cell may be formed by depositing a first or front electrode layer of TCO on a substrate. PV active material may be deposited on the first electrode layer. A second electrode layer can be deposited on the layer of PV active material. The layers may be deposited using deposition techniques, for example, physical vapor deposition techniques, chemical vapor deposition techniques, electrochemical vapor deposition techniques, etc. Thin film PV cells may comprise amorphous, monocrystalline, or polycrystalline materials, for example, thin-film silicon, CIS, CdTe or CIGS. Thin film PV cells facilitate small device footprint and scalability of the manufacturing process.

FIG. 3B is a block diagram schematically illustrating an example of a thin film PV cell 310. The PV cell 310 includes a glass substrate 311 through which light can pass. Disposed on the glass substrate 311 are a first electrode layer 312, a PV active layer 301 (shown as comprising amorphous silicon), and a second electrode layer 313. The first electrode layers 312 can include a transparent conducting material, for example, ITO. As illustrated, the first electrode layer 312 and the second electrode layer 313 sandwich the thin film PV active layer 301 therebetween. The illustrated PV active layer 301 comprises an amorphous silicon layer. As is known in the art, amorphous silicon serving as a PV material may comprise one or more diode junctions. Furthermore, an amorphous silicon PV layer or layers may comprise a p-i-n junction wherein a layer of intrinsic silicon 301c is sandwiched between a p-doped layer 301b and an n-doped layer 301a. A p-i-n junction may have higher efficiency than a p-n junction. In some other embodiments, the PV cell can comprise multiple junctions.

FIGS. 3C and 3D illustrate a PV device 330. As illustrated, the PV device 330 comprises front electrodes 331, 332 formed over a semiconductor wafer, for example, a silicon wafer. However, as will be appreciated from descriptions below, other PV devices may comprise a thin film photovoltaic material. PV devices including either thin film or wafer-type PV material can be interferometrically-enhanced (see FIG. 4A and attendant description). As illustrated in FIGS. 3C and 3D, many PV devices employ specular or reflective conductors on a front, or light-incident, side of the device as well as on a back side of the PV device 330. Conductors on the front or light-incident side can comprise bus electrodes 331 or gridline electrodes 332. When optical energy is absorbed by the PV active material 301, electron-hole pairs are generated. These electrons and holes can generate current by moving to one or the other of the front electrodes 331, 332 or back electrodes 333, as shown in FIG. 3D. The front conductors or electrodes 331, 332 are patterned to both reduce the resistance of the path an electron or hole must travel to reach an electrode while also allowing enough light to pass through to the PV active layer 301. The patterns of the front electrodes 331, 332 may include windows 334 to allow incident light to transmit to PV active material 301. While the PV device 330 is illustrated with front conductors or electrodes 331, 332 patterned and back electrodes 333 as unpatterned, those of skill in the art will understand that the back conductors or electrodes may also be patterned in a different manner. The front and back electrodes 331, 332, 333 may comprise reflecting metallic conducting material. In some embodiments, the front and back electrodes 331, 332, 333 may include transparent conductive materials, for example, ITO, or both transparent and reflective conducting materials.

Traditionally, the appearance of PV cells is dictated by the material comprising the electrodes and PV active material of the PV cells. However as the use of PV cells becomes more ubiquitous and new applications for PV cells emerge, designing and manufacturing colored PV cells may become important. Such colored cells may increase visual appeal and add aesthetic value. For example, there has been a lot of interest in designing and manufacturing building integrated PV applications (BIPV). The ability to pattern or blanket color on PV devices can aid in the acceptance of PV cells deployed on rooftops and facades of buildings, billboards, cars, electronic equipment, apparel, shoes, and many other locations that get exposed to light. Not only do interferometric stacks provide an ability to produce durable, fade-resistant color, but they also can produce a desired intensity and attractive color while still permitting design selection of the degree of light transmission through the interferometric stack.

Alternative methods to incorporate color into a PV cell are to add dyes or pigment of the appropriate color or add colored material in the PV stack. High absorption of light by such tinting, however, reduces the efficiency of the PV cell. Moreover, the colors have a tendency to fade in a shorter time than the lifespan of the PV device, particularly since the devices are often meant to be constantly exposed to sunlight.

Accordingly, the embodiments below describe “coloring” a PV cell by incorporating or integrating interferometric stacks with PV cells or devices. Using an interferometric stack, such as an absorber-spacer layer stack, on a PV device may allow for the appearance of a color reflecting from the interferometric stack hence imparting a “color” to the PV cell or device. Since the color of the reflection from an interferometric stack can be selected by using spacer layers of appropriate thickness and material (index of refraction), as well as by selecting and using appropriate thicknesses and materials for absorbers, an interferometric stack incorporated with a PV cell or device can be configured to reflect colors as desired for any particular application. The interferometric color reflecting effect can be affected by the thickness and material(s) of the spacer layer as well as the thickness and material(s) of the reflector and absorber materials. Accordingly, the color effect is not as susceptible to fading over time compared to common dyes or paints.

FIG. 4A illustrates an embodiment of a PV device or cell 410 incorporating an interferometric stack 401 to reflect a color. The device 410 comprises a photovoltaic active material 301 disposed over a second spacer layer 202b. The PV active layer 301 may comprise a thin film photovoltaic material, for example, amorphous silicon, CIGS or other thin semiconductor film photovoltaic material. The PV active layer may be between about 500 Å and 2000 Å. In the illustrated embodiment, the interferometric stack 401 covers a front side of the photovoltaic active material 301. The interferometric stack 401 may be an absorber-spacer layer stack comprising an absorber layer 201 disposed over a first spacer layer 202a. The illustrated front side of the interferometric stack 401 is transflective (e.g., simultaneously transmissive and reflective) and may be configured to reflect enough light so as to impart a color, yet transmit sufficient light so as to generate electricity. The interferometric stack 401, along with the PV active material 301 acting as a partial reflector, are configured to form an IMOD to interferometrically enhance reflections of one or more wavelength spectra within a visible range of wavelengths. The first and second spacer layers 202a,b each may comprise a TCO layer that serves both as an optically resonant spacer layer as well as a conducting layer for holes and/or electrons to conduct out of the PV active layer 301. The device 401 may further comprise a glass, polymer, or similar substrate layer 311 disposed over the absorber.

FIG. 4B depicts another example of an interferometrically enhanced PV device or cell 412 similar to the interferometrically enhanced PV device shown in FIG. 4A. In this embodiment, the interferometric stack 401 may comprise a color setting spacer 420 disposed between an absorber 201 and a first spacer layer 202a. The color setting spacer 420 may comprise an air gap or any other suitable optically resonant material. The PV active material 301 acts as a partial reflector. The thicknesses of the color setting spacer 420, the absorber 201, and first spacer layer 202a are such that the interferometric stack 401 is configured to enhance reflections of one or more wavelength spectra within a visible wavelength when coupled with the PV material 301. The thickness of the first spacer layer 202a and color setting spacer combined may be between about 500 Å and about 5000 Å. Also, the thickness of the absorber may be between about 20 Å and about 300 Å.

FIG. 4C depicts an example of an interferometrically enhanced PV device or cell 414. The interferometrically enhanced PV device 414 includes a PV active material or layer 301. The PV active layer 301 may comprise a thin film photovoltaic material, for example amorphous silicon, CIGS or other thin semiconductor film photovoltaic material formed under an interferometric stack 401 and glass substrate 311. The interferometric stack 401 may comprise an absorber 201 and a first spacer layer 202a. The interferometric stack 401 is configured to enhance reflections of one or more wavelength spectra within a visible range. A second spacer layer 202b disposed below the PV active material 301 and a reflector 413 disposed below the second spacer layer 202b are configured to interferometrically enhance the strength of the electric field in the PV active layer 301, resulting in an interferometrically enhanced PV device 414 with improved efficiency. The reflector 413 may comprise a partial or full reflector. In some embodiments, the PV active layer 301 may be covered in some areas with an opaque electrode (not shown) to facilitate the conduction of electrons and/or holes out of the PV active layer 301. Alternatively, in other embodiments, the first and second spacer layers 202a,b may comprise TCO layers that serve both as part of the optically resonant spacer layers 202a,b as well as a conducting layers for holes and or electrons to conduct out of the PV active layer 301. The optical properties (dimensions and material properties) of the reflector 413 and second spacer layer 202b are selected so that reflection from interfaces of the layered PV device 414 coherently sum to produce an increased field of a suitable wavelength distribution and phase in the PV active layer 301 of the photovoltaic cell where optical energy is converted into electrical energy. Such interferometrically enhanced photovoltaic devices increase the absorption of optical energy in the active region of the interferometric photovoltaic cell and thereby increase the efficiency of the device. As shown in the illustrated embodiment, multiple optically resonant spacer layers may be employed to separately tune different wavelengths of light and maximize absorption in the PV active layer. The buried spacer layers may comprise transparent conductive or dielectric materials, air gaps, or combinations thereof.

FIG. 4D illustrates an embodiment of a PV device or cell incorporating an interferometric stack 401 to reflect a color. The PV device 400 comprises a photovoltaic (PV) active material 301. In the illustrated embodiment, the interferometric stack 401 covers a front side of the photovoltaic active material 301. In various embodiments, the interferometric stack 401 may comprise an absorber-spacer layer stack, as shown in FIGS. 4A and 4C, with the PV active layer 301 acting as a partial reflector and front electrodes 331, 332 acting as reflectors. The illustrated front side interferometric stack 401 is transflective (i.e., simultaneously transmissive and reflective) and may be configured to reflect enough light so as to impart a color, yet transmit sufficient light so as to generate electricity. A light ray 402 incident upon the interferometric stack 401 may be characterized as having a spectral distribution 402a that expresses the various wavelength components present in light ray 402. As illustrated, light ray 402 comprises a broad spectrum of wavelengths in the visible range, from 400 to 750 nm and may hence represent light incident from an ambient white light source, for example, the sun or artificial man-made lighting. Ray 402 incident upon PV device 400 is partly reflected by the interferometric stack 401, as indicated by ray 403, and partly transmitted in rays 404 and 405. The interferometric stack 401, along with the PV active layer 301 acting as a partial reflector, are configured to interferometrically enhance reflections of one or more wavelength spectra within a visible range of wavelengths. Therefore, reflected ray 403 may also be characterized as having a spectral distribution 403a. The spectral distribution may comprise one or more wavelength spectra or ranges such that the reflected ray 403 has a relatively high intensity of one or more wavelengths of light compared to others in the visible range. As a result of the selective enhancement of one or more wavelengths in reflected ray 403, a viewer viewing the PV device 400 from the light incident side will perceive a coherent color to the interferometric stack 401, and hence, the PV device 400.

As noted above with respect to FIG. 3D, some embodiments of PV cells or devices include front or back electrodes as well as windows 334 patterned to allow transmission of light to the photovoltaic active material. As shown in FIG. 4D, light ray 402 incident within the window region 334 may be transmitted through the interferometric stack 401 along rays 404 and 405. The interferometric stack can be configured to both enhance reflection of some portion of the light so as to impart a color appearance while still transmitting substantial portions of incident light 402, as represented by a transmitted ray 405.

In some applications, it may be desired to minimize reflections from the front side of a PV device. In other embodiments, a PV cell may incorporate a particular interferometric stack to reflect one or more specific colors that deliberately enhances the reflection of some wavelengths of light. Because reflecting a particular wavelength may also affect the efficiency of the PV cell, there may be a tradeoff between the efficiency and the aesthetic appeal of a PV cell which reflects colors matching the surrounding environment in various applications, for example, buildings, signs, or billboards. Referring again to FIG. 4D, in some embodiments, the reflectivity of visible light reflected out of the interferometric stack 401, including portions over the front side of the window 334 exposing the PV active material 301, is greater than 10%. In other embodiments, it is greater than 15%, relative to visible incident light. In these embodiments, at least 10% or 15% of the incident visible light is lost in addition to any losses due to absorption in the interferometric stack 401. In other embodiments, the reflectivity may be as high as about 35%. However, this may be acceptable due to the desire to increase aesthetics of a PV device 400 with an interferometric stack 401 and consequent more widespread acceptance may lead to overall greater capture of solar energy. Additionally, efficiency losses due to an interferometric stack configured to reflect a certain color may be minimized by adding a second interferometric stack to enhance the efficiency the PV device 400 by reflecting light of a particular wavelength back into the PV active material 301, as shown in FIG. 4C.

Still referring to FIG. 4D, in various embodiments the light reflected in ray 403 may have various characteristics depending on the optical properties of the absorber or spacer layers within the interferometric stack 401. Hence, ray 403 may have a spectral distribution 403a that is different than the spectral distribution of the incident light 402a. Spectral distribution 403a of the light reflected out of the interferometric stack is not flat within the visible range of wavelengths. That is, in some embodiments, the spectral distribution 403a comprises one or more peaks corresponding to one or more peak wavelengths at which reflectance is higher than for other wavelengths. The peak(s) result in a particular colored appearance, against the background of depressed reflectivity of other visible wavelengths. In some embodiments, the reflectivity or reflectance at a peak wavelength may be much higher than the overall visible reflectivity. In such embodiments, the peak reflectance may be as high as 20% to 95% when reflecting off of the front electrodes 331, 332. The distribution will also comprise wavelengths near the peak wavelength at which reflectance is relatively high, but not as high as the reflectance at peak wavelength. The reflectivity at the peak(s) may therefore be characterized by bandwidths, for example, half-peak bandwidths. The half-peak bandwidth for a reflectivity spike is the width of the band at a reflectance equal to half the reflectance at peak wavelength. In some embodiments, the half-peak bandwidth of a peak or spike in the reflected wavelength spectra is equal to or less than 150 nm. Particularly, the half-peak bandwidth of a spike in the reflected light distribution may be between 50 nm and 100 nm. In some embodiments, the spectral distribution of the reflected light comprises a single peak. In other embodiments, the spectral distribution may comprise multiple spikes or pulses centered around multiple reflectance peaks, each peak corresponding to a peak wavelength.

Still referring to FIG. 4D, the PV active material or layer 301 may comprise a deposited thin film, or may be formed by portions of single crystal, semiconductor substrates and/or epitaxial layers thereover. A deposited thin film PV active material can comprise, for example, an amorphous silicon thin film, which has recently been gaining in popularity. Amorphous silicon as thin films can be deposited over large areas by physical vapor deposition (PVD), chemical vapor deposition (CVD), electro-chemical vapor deposition, or plasma-enhanced chemical vapor deposition (PECVD), among other techniques. As is known by those with skill in the art, PV active materials comprising amorphous silicon layers may include one or more junctions with n-doped and/or p-doped silicon and may further comprise p-i-n junctions. The PV active material 301 may comprise other appropriate materials, including germanium (Ge), Ge alloys, and alloys like copper indium gallium selenide (CIGS), cadmium telluride (CdTe), as well as III-V semiconductor materials, or tandem multi-junction photovoltaic materials and films. Ill-V semiconductor materials include such materials as gallium arsenide (GaAs), indium nitride (InN), gallium nitride (GaN), boron arsenide (BAs). Semiconductor alloys like indium gallium nitride may also be used. Other photovoltaic materials and devices are also possible. Methods of forming these materials are known to those having skill in the art. As an illustrative example, alloys like CIGS can be formed by a vacuum-based process where copper, gallium, and indium are co-evaporated or co-sputtered then annealed with a selenide vapor to form the CIGS structure. Non-vacuum-based alternative processes are also known to those of skill in the art.

As shown in FIG. 4D, the PV layer 301 is configured as a second partial reflector in the IMOD. In other words, the PV layer 301 itself can be configured as a partial reflector and perform the same function as reflector 203 in FIG. 2B. In such embodiments, the PV layer 301 forms an IMOD when combined with an interferometric stack 401. When the PV layer 301 comprises a deposited thin film, the PV layer 301 may have thickness between about 1000 Å and about 100,000 Å. To form an IMOD, a PV layer 301 that is at least partially reflective may be combined with an interferometric stack 401. The thickness of the PV layer 301 may be selected to affect the transparency of the PV device 400. Additionally, the design of the interferometric stack 401 may vary according to the thickness of the PV layer 301. For example, when the PV device 400 is designed to be semi-transparent, the PV active layer 301 may be less thick and the interferometric stack 401 may be configured to optimize transmission through the PV layer 301. Additionally, when the PV layer 301 comprises a deposited thin film, opaque front and rear electrodes, for example, electrodes 331, 332, and 333 shown in FIG. 4D, may not be required. The interferometric stack 401, shown in FIGS. 4A and 4B containing spacer layer 202a and absorber 201, may be tuned separately from the PV device 400 to reflect a particular color.

FIG. 4E illustrates a graph of reflectance of an interferometric stack (for example, the interferometric stack 401 of FIGS. 4A or 4B) versus wavelength as seen from a direction normal or perpendicular to the front surface of the stack. This graph depicts the wavelength spectrum of the reflected light which may generally be different from the wavelength spectrum of the light incident on the stack. In the illustrated graph, the reflectance is maximized around a peak 450 of approximately 575 nm. Peak 450 also has a half-peak bandwidth 452, which is the width of the peak at a reflectance 453 equal to half of the peak or maximum reflectance 454. The location of the peak of the total reflection curve can be shifted by changing the material thickness of one or more layers in the stack.

FIG. 4F illustrates a CIE 1931 chromaticity diagram depicting the color reflected from the front (substrate) side of a photovoltaic cell comprising an a-silicon active layer configured as shown in FIG. 4A as the thickness of the first spacer layer is varied. The photovoltaic cell includes a molybdenum absorber layer with a thickness of 20 Å and an α-silicon active layer with a thickness of 1000 Å. The color reflected from the front side of the PV cell as the thickness of the first spacer layer is varied is shown by a series of dots 496. To create the series 496, the thickness of the first spacer layer was varied from 1000 Å to 4000 Å. As can be appreciated by the series representing the reflected light 496, a PV cell configured as shown in FIG. 4A is capable of reflecting a wide range of colors.

FIG. 4G illustrates a CIE 1931 chromaticity diagram depicting the color reflected from the front (substrate) side of a photovoltaic cell comprising a copper indium gallium diselenide (CIGS) active layer configured as shown in FIG. 4A as the thickness of the first spacer layer is varied. The photovoltaic cell includes a molybdenum absorber layer with a thickness of 20 Å and an α-silicon active layer with a thickness of 1000 Å. The color reflected from the front side of the PV cell as the thickness of the first spacer layer is varied is also shown by a series of dots 497. To create the series 497, the thickness of the first spacer layer was varied from 1000 Å to 4000 Å. As can be appreciated by the series representing the reflected light 497, a PV cell comprising a CIGS layer configured as shown in FIG. 4A may also reflect a wide range of colors.

FIG. 4H shows a CIE 1931 chromaticity diagram depicting color transmitted through the a PV cell or device configured as shown in FIG. 4A as the thickness of the first spacer layer is varied. The photovoltaic cell includes a molybdenum absorber layer with a thickness of 20 Å and an α-silicon active layer with a thickness of 1000 Å. The color transmitted through the PV device as the thickness of the first spacer layer is varied is shown by a series of dots 498. To create the series 498, the thickness of the first spacer layer was varied from 1000 Å to 4000 Å. As shown by the series representing transmitted light 498, varying the thickness of the first spacer layer has little effect on transmitted light.

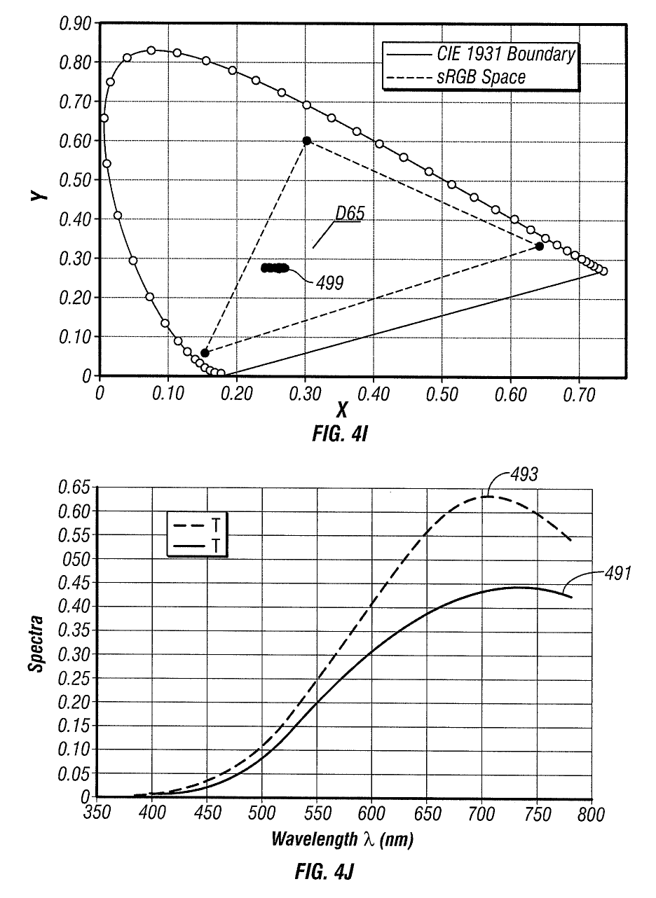

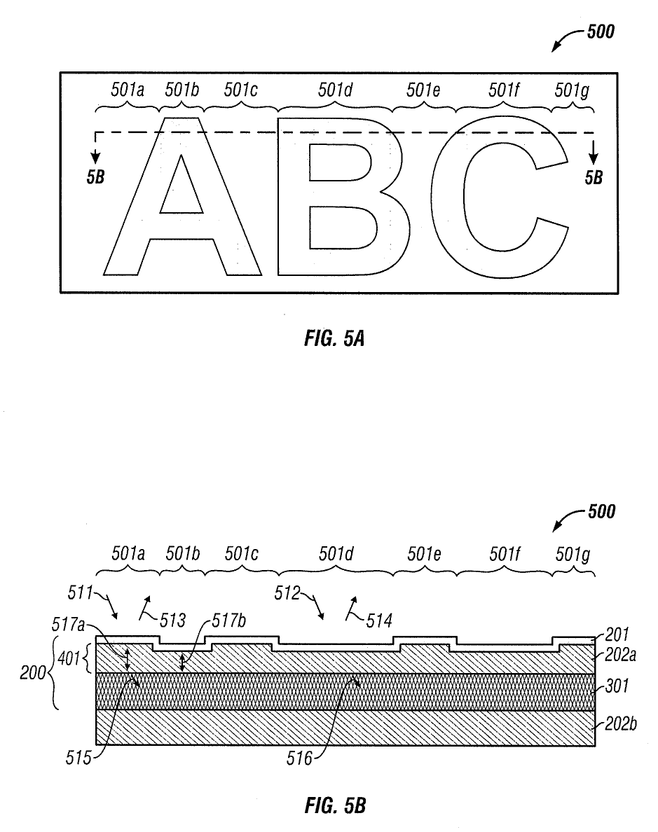

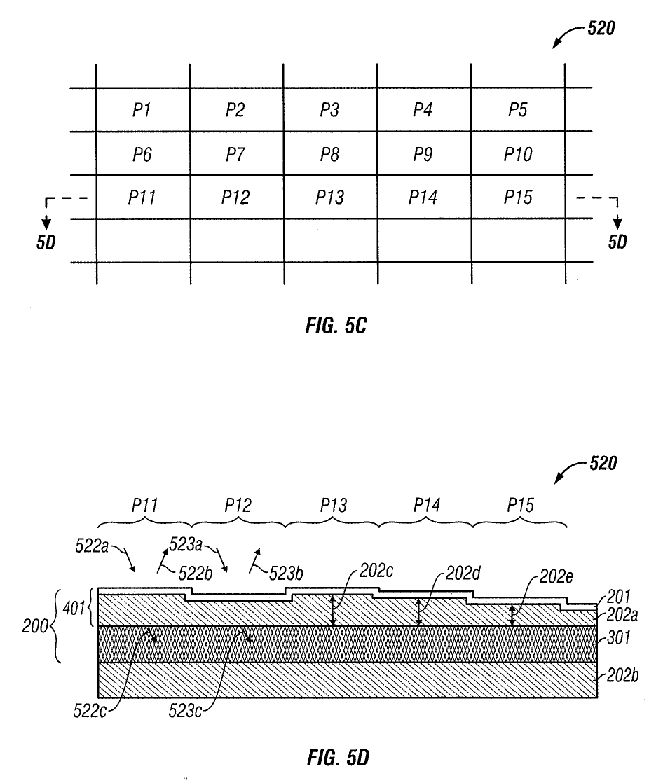

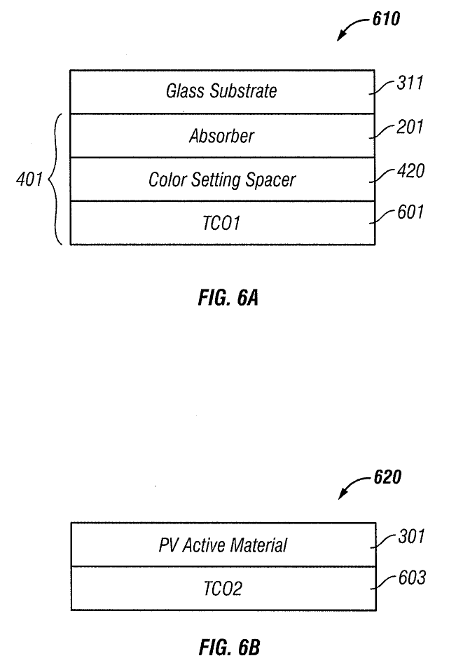

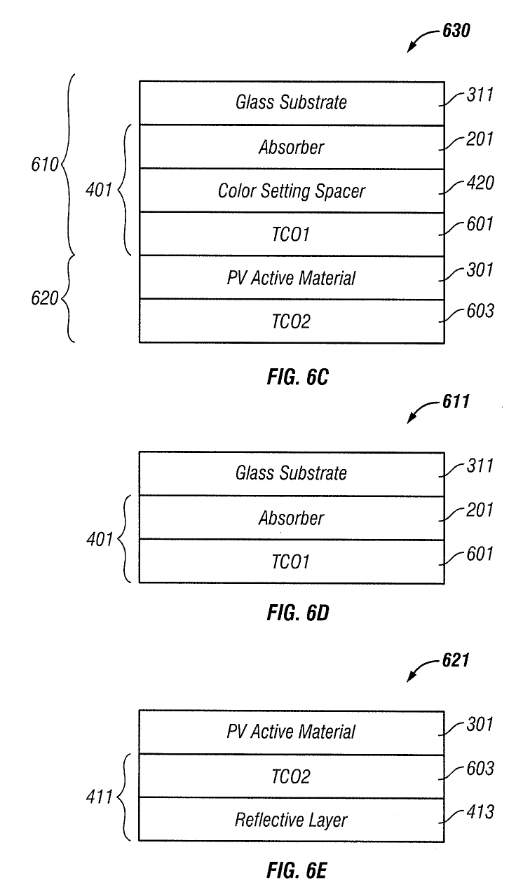

FIG. 41 shows a CIE 1931 chromaticity diagram depicting color reflected from the rear (PV active material) side of a PV cell configured as shown in FIG. 4A away from the PV cell as the thickness of the first spacer layer is varied. The photovoltaic cell includes a molybdenum absorber layer with a thickness of 20 Å and an α-silicon active layer with a thickness of 1000 Å. The color reflected from the second spacer layer as the thickness of the first spacer layer is varied is shown by a series of dots 499. To create the series 499, the thickness of the first spacer layer was varied from 1000 Å to 4000 Å. As shown by the series representing reflected light 499, varying the thickness of the first spacer layer has little effect on light reflected from the rear (PV active material) side of the PV cell.

FIG. 4J illustrates a graph of light transmission versus wavelength of two photovoltaic cells. The first photovoltaic cell is configured as shown in FIG. 4A and includes a molybdenum absorber with a thickness of 20 angstroms. The transmission of light versus wavelength of this photovoltaic cell is depicted by line 491. The second photovoltaic cell is configured without a spacer layer as shown in FIG. 3B and thus does not have an absorber. The transmission of light versus wavelength of this second photovoltaic cell is depicted by line 493. As shown in FIG. 4J, adding a thin absorber has a limited impact on light transmission through a photovoltaic cell and very thin absorber layers, for example, the one used to create line 491, are able to produce bright colors. Accordingly, the choice of absorber can be made to optimize transmission and color according to requirements. Alternative materials for the absorber layer may include chromium, titanium, aluminum, or silicon.

FIG. 5A depicts an embodiment of a PV device with different reflected colors in different regions, configured to display a particular image, shape, information, or characters as in a display, sign, or billboard. In FIG. 5A, a static display 500 contains multiple regions 501a-501g of uniform color. For example, the background (regions 501a, 501c, 501e, and 501g along cross-section 5B) may be yellow, red, green, or white or black. The letters “ABC” (regions 501b, 501d, and 501f in cross-section 5B) may be darker. For example, letters “ABC” may be blue.

FIG. 5B shows a cross section of a PV display device 500. As shown in FIG. 5B, light rays 511 and 512 incident upon the interferometric stack 401 are partly reflected as indicated by rays 513, 514, and partly transmitted along rays 515 and 516. In the illustrated cross-section, the interferometric stack 401 comprises an absorber 201 and a first spacer layer 202a. The IMOD 200 comprises the interferometric stack 401 and a PV active material 301. The PV active material 301 is disposed upon a second spacer layer 202b. As shown in FIG. 5B, the height or thickness of the first spacer layer 202a is not uniform. The first spacer layer 202a is patterned such that the interferometric stack 401 comprises multiple regions 501a-501g with different spacer layer heights corresponding to a different reflected color. As illustrated, the static display 500 comprises a first spacer layer 202a with two spacer layer heights corresponding to two different colors. However, the display 500 may comprise more than two heights and thus more than two reflected interferometric display colors. As shown in FIG. 5B, regions 501a, 501c, 501e, and 501g have a relatively large spacer layer height 517a. On the other hand, regions 505b, 505d, and 505f have a smaller spacer layer height 517b. These different heights are configured to result in reflections of different peaks (at different peak wavelengths) for reflected rays 513, 514. In this way, one region of the display will show one color, and another region will show a different color. In at least one of the regions, the interferometric stack 401 can be configured to reflect enough light so as to display a visible color, while also transmitting sufficient light to PV material 301 to generate electricity. Hence while incident rays 511 and 512 are partly reflected in rays 513 and 514, sufficient light may be transmitted in at least one of rays 517 and 518 to allow for the generation of an electrical current in the photovoltaic material 301. FIG. 5B depicts a thin film PV device. However, as will be appreciated by the skilled artisan, a PV device 500 may comprise a traditional PV active layer with front electrodes that may be situated between the first spacer layer 202a and the photovoltaic material 301. Similarly, those of skill in the art will appreciate that PV device 500 may comprise layers not shown here, for example, anti-reflective coatings, diffusers, or passivation layers over the PV active layer 301 or interferometric stack 401. Also, the PV device 500 may comprise regions of continuous color variation, rather than distinct regions of uniform color. As will be readily appreciated by one of skill in the art, continuous color variation can be accomplished using interferometric stack 401 by continuously varying the height of the first spacer layer 202a or absorber 201.

FIGS. 5C and 5D depict another embodiment of a PV display device 520. In FIG. 5C, the image or pattern displayed on the PV display device 520 is pixilated such that any image is made up of multiple pixels P1-P15. Hence the image or pattern comprises a regular array of pixels as shown in FIG. 5C. As will be appreciated by one of skill in the art, pixilation may be convenient for the transfer of digital images onto a static interferometric stack as shown in FIG. 5C. FIG. 5D is a cross-section of FIG. 5C showing an embodiment of a pixilated PV display device 520. As illustrated, an interferometric stack 401 comprises an absorber 201 and a static, variable height first spacer layer 202a patterned so as to form pixels. The PV active material 301 is disposed upon a second spacer layer 202b. The IMOD 200 comprises the interferometric stack 401 and a PV active material layer 301 that acts as a partial reflector. Each pixel P1-P15 may be formed by a region of a uniform interferometric sub-stack such that one pixel may be made up of a discrete absorber and a first spacer layer. For example, pixel P13 may be made up of the absorber 201 and the spacer layer 202c. The absorber 201, as well as spacer layers 202d and 202e similarly form pixels P14 and P15 in the pixel array, respectively. As illustrated spacer layers 202c, 202d, 202e may have different heights, resulting in different colored pixels. In other embodiments, for example, in a region of uniform color, several adjacent spacer layers may have roughly equal heights.

In an RGB scheme, pixels P1-P15 may comprise red pixels, green pixels, and blue pixels. More generally, a regular array of pixels may comprise a plurality of red pixels, a plurality of green pixels, and a plurality of blue pixels. Hence, for example, the spacer layer 202c may form a red pixel, while spacer layer 202d may form a green pixel, and spacer layer 202e may form a blue pixel. Other color schemes are also possible, for example, CMY (cyan, magenta, yellow), RYB (red, yellow, blue), and VOG (violet, orange, green), among others. As shown in FIG. 5D, the height of the spacer layers 202c, 202d, 202e is primarily varied to vary color. However, the absorber 201 thickness may also be varied from pixel to pixel, along with the spacer layer thickness. This allows flexibility to have any desirable color (hue) and shade (saturation and lightness) in any pixel, as the height of any or all of the absorber 201 or the spacer layer can be tailored as necessary.

As shown in FIG. 5D, light rays 522a, 523a incident upon pixels P11, P12 in pixilated interferometric stack 401 are partly reflected as indicated by rays 522b, 523b and partly transmitted along rays 522c, 523c. Reflected rays 522b, 523b may contain different wavelength distributions and hence may reflect or display different colors depending upon the height or thickness of the spacer layer for pixels P11 and P12. As mentioned above, to allow for reasonable electricity generation, the interferometric stack 401 may be configured to reflect enough light to display a color while allowing sufficient light to transmit to the photovoltaic active material layer 301 along rays 522c, 523c.

The variable height first spacer layer 202a in FIG. 5D may comprise a dielectric material, for example, silicon dioxide or other suitable optically transmissive or transparent medium. The first spacer layer 202a may comprise a conductor, for example, a TCO or other transparent conducting material. Furthermore, in some embodiments, the first spacer layer 202a may comprise an air gap or other color setting spacer. In such an embodiment, supports 211 (see FIG. 2C) may help to form the air gaps.

FIGS. 6A-6E illustrate one example of a process for fabricating a PV device 630 incorporating an interferometric stack 401. The example employs a deposited thin film of PV active material layer 301 (FIG. 6B). As illustrated in FIG. 6A, a method of manufacturing such a device can comprise providing an interferometric 401 formed on a glass substrate 311 to create a starter stack 610. The interferometric stack 401 comprises an absorber 201, a color setting spacer 420, for example, an air gap or other optically resonant layer, and a first TCO 601. The starter stack 610 can be configured (or “pre-tuned”) to reflect a certain color or wavelength when a reflector is deposited on it, for example, a PV active material acting as a partial reflector or a series of layers acting in concert as a composite reflector. The stack 610 may be tuned by adjusting the thickness of the absorber layer 201, the thickness of the color setting spacer 420, the thickness of the first TCO 601, or the color setting spacer 420. Additionally, the stack 610 may be pre-formed to be one piece.

With reference to FIG. 6B, the method can employ a photovoltaic stack 620 comprising a second TCO layer 603 with a photovoltaic active material layer 301 deposited on it. In the illustrated embodiment, the photovoltaic active material layer 301 comprises a thin film. In other embodiments, portions of single crystal, semiconductor substrates and/or epitaxial layers thereover are employed. The method of manufacture of the photovoltaic stack 620 may depend on the design of the cell. For example, when thin film PV materials are used as the PV active material 301, the manufacturing begins with a substrate and layers are deposited upon the substrate in sequence. As another example, when wafer based PV materials are used as the PV active material 301, layers may be directly deposited on the PV wafer itself. A deposited PV active material layer can comprise, for example, an amorphous silicon thin film. Amorphous silicon as thin films can be deposited over large areas by physical vapor deposition, chemical vapor deposition, electro-chemical vapor deposition, or plasma-enhanced chemical vapor deposition as well as other methods known to those of skill in the art. As is known by those with skill in the art, PV active material layers comprising amorphous silicon layers may include one or more junctions with n-doped and/or p-doped silicon and may further comprise p-i-n junctions. Other appropriate materials for the PV active material layer 301 include germanium (Ge), Ge alloys, and alloys like copper indium gallium selenide (CIGS), cadmium telluride (CdTe), as well as III-V semiconductor materials, or tandem multi-junction photovoltaic materials and films. III-V semiconductor materials include such materials as gallium arsenide (GaAs), indium nitride (InN), gallium nitride (GaN), boron arsenide (Bas). Methods of forming these materials are known to those having skill in the art. As an illustrative example, allows like CIGS can be formed by a vacuum-based process where copper, gallium, and indium are co-evaporated or co-sputtered then annealed with a selenide vapor to form the final CIGS structure. Non-vacuuming based alternative processes are also known to those of skill in the art. The stack 620 may be pre-formed to be once piece. In other embodiments, the transparent conductive oxide layer 603 comprises a non-transparent substrate, for example, a metal material. In these embodiments, the PV active material 301 may be deposited upon the non-transparent substrate and additional layers may then be deposited upon the PV active material 301.

As shown in FIG. 6C, with access to the starter stack 610 depicted in FIG. 6A and the capability of producing photovoltaic stack 620 depicted in FIG. 6B the method of manufacturing includes depositing the photovoltaic stack, layer by layer, upon the starter stack 610 to create PV device 630. For example, a third party may supply a quantity of starter stacks 610 to a PV device manufacturer and the PV device manufacturer may then form stacks 620 on stacks 610 by depositing a PV active material layer 301 upon stack 610 and then depositing a transparent conductive oxide layer 603 upon the PV active material layer 301 resulting in a PV device 630. In another embodiment, PV device 630 may be manufactured in a monolithic process. PV device 630 is configured to reflect a certain color based on the tuning of starter stack 610. As shown in FIG. 4A, the photovoltaic active material 301 acts as a partial reflector to compliment interferometric stack 401 incorporated in starter stack 610. This method of manufacturing allows a manufacturer to make or access a large quantity of pre-tuned starter stacks 610 and then deposit PV stacks 620 upon the starter stacks 610. Because both the starter stack 610 may be pre-formed to be a single piece, the PV device 630 may be formed by depositing just two layers upon a pre-formed starter stack. This provides flexibility in reflected color or appearance for photovoltaic device manufacturers by allowing PV device makers to order multiple starter stacks 610 configured to reflect a variety of colors to assemble colored PV devices with the same base PV stack 620.

FIGS. 6D shows a different embodiment of a starter stack 611. In the illustrated figure, the starter stack comprises a glass substrate deposited upon a pre-tuned interferometric stack 401. In this embodiment, the pre-tuned interferometric stack 401 comprises an absorber layer 201 and a first TCO layer 601. In order to pre-tune starter stack 611, a manufacturer must either adjust the thickness of the absorber layer 201, the thickness of the first TCO layer 601, or the thicknesses of the first TCO layer 601 and absorber layer 201. Once the starter stack 621 is pre-tuned, a PV stack, for example the PV stacks depicted in FIGS. 6B and 6E, may be deposited on the starter stack in layers.

FIG. 6E shows an alternative embodiment of a PV stack 621 comprising a photovoltaic active layer 301 deposited on a second TCO layer 603 and a reflector 413. The reflector 413 may comprise a partial reflector, a full reflector, or a series of layers acting in concert to form a composite reflector. The second TCO layer 603 and reflector 413 create an interferometric stack 411 to enhance photovoltaic efficiency as discussed in FIG. 4C. The PV stack 621 may be deposited upon either starter stack 610 or starter stack 611 to create a photovoltaic device with multiple interferometric stacks. At least one stack 401 would be configured to reflect a certain color from the front of the PV device and at least one stack 411 would be configured to enhance the photovoltaic efficiency of the device.

While the foregoing detailed description discloses several embodiments of the invention, it should be understood that this disclosure is illustrative only and is not limiting of the invention. It should be appreciated that the specific configurations and operations disclosed can differ from those described above, and that the methods described herein can be used in contexts other than fabrication of semiconductor devices. The skilled artisan will appreciate that certain features described with respect to one embodiment may also be applicable to other embodiments. For example, various features of an interferometric stack have been discussed with respect to the front side of a photovoltaic cell, device or array, and such features are readily applicable to an interferometric stack formed over a back side of a photovoltaic cell, device or array. For example, various spacer layer features have been discussed with respect to various embodiments of interferometric stacks formed over a front side of a PV device. Such spacer layer features are also applicable to interferometric stacks formed over a back side of a PV device.

What is claimed is:

1. A photovoltaic device defining a front side on which light is incident, the photovoltaic device comprising:
a photovoltaic active layer having a front side and a back side;
an absorber layer; and
a first optical resonant cavity defined by the front side of the photovoltaic active layer and the absorber layer.

2. The device of claim 1, wherein the first optical resonant cavity comprises a first spacer layer.

3. The device of claim 2, wherein the spacer layer comprises a transparent conductive oxide layer.

4. The device of claim 1, wherein the first optical resonant cavity has a height between 700 Å and 5000 Å.

5. The device of claim 3, wherein the first spacer layer further comprises a color setting spacer disposed between the absorber layer and the transparent conductive oxide layer.

6. The device of claim 1, further comprising a second optical resonant cavity.

7. The device of claim 6, further comprising a reflector, and wherein the second optical resonant cavity is defined by the back side of the photovoltaic active layer and the reflector.

8. The device of claim 6, wherein the second optical resonant cavity comprises a second spacer layer.

9. The device of claim 7, wherein the reflector comprises metal.

10. The device of claim 8, wherein the second spacer layer comprises transparent conductive oxide.

11. The device of claim 1, wherein the first optical resonant cavity is configured to reflect a uniform color.

12. The device of claim 1, wherein the photovoltaic layer comprises photovoltaic material selected from the group consisting of single crystal silicon, amorphous silicon, germanium, III-V semiconductors, copper indium, gallium selenide, cadmium telluride, gallium arsenide, indium nitride, gallium nitride, boron arsenide, indium gallium nitride, and tandem multi-junction photovoltaic materials.

13. The device of claim 1, wherein a height of the first optical resonant cavity is not uniform across the photovoltaic device.

14. The device of claim 13, wherein the first optical resonant cavity height is patterned such that the photovoltaic device comprises two or more regions, each region with a different first optical resonant cavity height corresponding to a different reflected color.

15. The device of claim 1, wherein a height of the first optical resonant cavity is uniform across the photovoltaic device.

16. The device of claim 1, wherein a height of the absorber is not uniform across the photovoltaic device.

17. The device of claim 1, wherein the absorber layer has a thickness between 20 Å and 300 Å.

18. The device of claim 1, wherein the absorber layer has a thickness between 20 Å and 35 Å.

19. The device of claim 1, wherein the absorber layer comprises metal.

20. The device of claim 1, wherein the photovoltaic active layer comprises a thin film photovoltaic material.

21. The device of claim 20, wherein the thin film comprises amorphous silicon.

22. A method of manufacturing a photovoltaic device, the method comprising:
providing an interferometric stack comprising an absorber layer on a substrate and a first optical resonant cavity defined on a first side by the absorber layer; and
depositing a photovoltaic active layer on the interferometric stack, the photovoltaic active layer defining a second side of the first optical resonant cavity.

23. The method of claim 22, wherein the interferometric stack is pre-tuned to reflect a certain color when the photovoltaic active layer is deposited upon it.

24. The method of claim 22, wherein the first optical resonant cavity comprises a first spacer layer.

25. The method of claim 24, wherein the spacer layer comprises a transparent conductive oxide.

26. The method of claim 22, wherein the first optical resonant cavity has a height between 500 Å and 5000 Å.

27. The method of claim 22, wherein the absorber layer has a thickness between 20 Å and 300 Å.

28. A photovoltaic device comprising:
an interferometric modulator comprising a photovoltaic active layer.

29. The photovoltaic device of claim 28, wherein the photovoltaic active layer has a front side and a back side and the device further comprises a first optical resonant cavity defined by the front side of the photovoltaic active layer.

30. The device of claim 29 wherein the first optical resonant cavity comprises a first spacer layer.

31. The device of claim 30, wherein the first spacer layer comprises a transparent conductive oxide layer.

32. The device of claim 29, further comprising an absorber layer, the absorber layer configured to reflect at least some light and transmit at least some light.

33. The device of claim 29, further comprising a second optical resonant cavity defined by the back side of the photovoltaic active layer.

34. The device of claim 32, wherein the absorber layer has a thickness between 20 Å and 300 Å.

35. The device of claim 28, wherein the first optical resonant cavity has a height between 300 Å and 5000 Å.

36. The device of claim 33, further comprising a reflector configured to reflect at least some light and wherein the second optical resonant cavity is disposed between the back side of the photovoltaic active layer and the reflector.

37. The device of claim 36, wherein the reflector is a partial reflector.

38. The device of claim 28, wherein the photovoltaic active layer comprises a thin film photovoltaic material.

39. A photovoltaic device defining a front side on which light is incident, the photovoltaic device comprising:
a first means for partially reflecting light incident on the front side;
a second means for partially reflecting light incident on the front side that has passed through the first means; and
a first optical resonant cavity defined by the first means and the second means.

40. The device of claim 39, wherein the first means comprises a photovoltaic active layer.

41. The device of claim 39, wherein the second means comprises an absorber layer.
